(19) United States
(12) Patent Application Publication
(10) Pub. No.: US 2021/0336413 A1
(43) Pub. Date: Oct. 28, 2021

(54) LASER DIODE DRIVE CIRCUIT AND COMMUNICATION DEVICE

(71) Applicant: Mitsubishi Electric Corporation, Tokyo (JP)

(72) Inventors: Ryota KOBAYASHI, Tokyo (JP); Yuichi SASAKI, Tokyo (JP); Chiharu MIYAZAKI, Tokyo (JP)

(73) Assignee: Mitsubishi Electric Corporation, Tokyo (JP)

(21) Appl. No.: 17/369,539

(22) Filed: Jul. 7, 2021

Related U.S. Application Data
(63) Continuation of application No. PCT/JP2019/003856, filed on Feb. 4, 2019.

(51) Int. Cl. H01S 5/042; H04B 10/50

(52) U.S. Cl. CPC H01S 5/042; H04B 10/503

(57) ABSTRACT

A laser diode drive circuit includes: a laser diode; a differential line including a first signal line having a first end connected with an anode terminal of the laser diode and a second signal line having a first end connected with a cathode terminal of the laser diode; first power supply wiring having a first end connected with a positive side terminal of a direct current power supply and a second end connected with the anode terminal; second power supply wiring having a first end connected with a negative side terminal of the direct current power supply and a second end connected with the cathode terminal; a first capacitor inserted in the first signal line; and a second capacitor inserted in the second signal line. In the laser diode drive circuit, at least one of the first capacitor and the second capacitor is a variable capacitor.

### CROSS REFERENCE TO RELATED APPLICATION

This application is a Continuation of PCT International Application No. PCT/JP2019/003856, filed on Feb. 4, 2019, which is hereby expressly incorporated by reference into the present application.

### TECHNICAL FIELD

The present invention relates to a laser diode drive circuit including a laser diode and a communication device.

### BACKGROUND ART

Patent Literature 1 below discloses an optical transmitter including a semiconductor laser drive circuit for supplying a high-frequency modulation current based on a data signal between an anode terminal and a cathode terminal of a semiconductor laser via a differential line.

The semiconductor laser described in Patent Literature 1 outputs modulated laser light on the basis of a modulation current output from the semiconductor laser drive circuit.

### CITATION LIST

### Patent Literature

Patent Literature 1: JP 2005-252783 A

### SUMMARY OF INVENTION

### Technical Problem

The semiconductor laser of the optical transmitter disclosed in Patent Literature 1 cannot output modulated laser light unless the semiconductor laser is supplied with power. Therefore, it is necessary in the semiconductor laser that the anode terminal be connected with a positive side terminal of a DC power supply via first power supply wiring and that the cathode terminal be connected with a negative side terminal of the DC power supply via second power supply wiring.

In a case where the optical transmitter includes the first and second power supply wiring and a differential line, parasitic capacitance is formed between the first power supply wiring and the differential line (hereinafter referred to as the “first parasitic capacitance”), and parasitic capacitance is formed between the second power supply wiring and the differential line (hereinafter referred to as the “second parasitic capacitance”).

When the first and second parasitic capacitance are formed, noise is induced to the differential line from the first and second power supply wiring via a portion forming the first parasitic capacitance or a portion forming the second parasitic capacitance. At this point, in a case where the first parasitic capacitance and the second parasitic capacitance are different, the potential difference between the anode terminal and the cathode terminal of the semiconductor laser fluctuates due to the noise induced to the differential line. There are disadvantages that, when the potential difference between the anode terminal and the cathode terminal fluctuates due to noise, the correspondence relationship between the modulation current and the modulated laser light is lost and that the laser diode may erroneously emit light or erroneously go off

The present invention has been made to solve the above-mentioned disadvantages, and it is an object of the present invention to obtain a laser diode drive circuit and a communication device each capable of preventing both of erroneous emission of light and erroneous extinction of light of a laser diode even when noise is induced to a differential line from power supply wiring via a portion forming parasitic capacitance.

### Solution to Problem

A laser diode drive circuit according to the present invention includes: a laser diode; a differential line including a first signal line having a first end connected with an anode terminal of the laser diode and a second signal line having a first end connected with a cathode terminal of the laser diode; first power supply wiring having a first end connected with a positive side terminal of a direct current power supply and a second end connected with the anode terminal; second power supply wiring having a first end connected with a negative side terminal of the direct current power supply and a second end connected with the cathode terminal; a first capacitor inserted in the first signal line; and a second capacitor inserted in the second signal line. At least one of the first capacitor and the second capacitor is a variable capacitor.

### Advantageous Effects of Invention

According to the present invention, the laser diode drive circuit is configured so that at least one of the first capacitor and the second capacitor is a variable capacitor. Therefore, a laser diode drive circuit according to the present invention is capable of preventing both of erroneous emission of light and erroneous extinction of light of a laser diode even when noise is induced to a differential line from first and second power supply wiring via portions forming parasitic capacitance.

### BRIEF DESCRIPTION OF DRAWINGS

FIG. 1 is a configuration diagram illustrating a communication device including a laser diode drive circuit 2 according to a first embodiment.

FIG. 2 is a configuration diagram illustrating the laser diode drive circuit 2 according to the first embodiment.

FIG. 3 is an explanatory diagram illustrating paths of noise currents I₁ to I₄ flowing in a differential line 12.

FIG. 4 is a diagram illustrating the pattern of a first layer 50a of a substrate 50 on which the laser diode drive circuit 2 illustrated in FIG. 2 is mounted.

FIG. 5 is a diagram illustrating the pattern of a second layer 50b of the substrate 50 on which the laser diode drive circuit 2 illustrated in FIG. 2 is mounted.

FIG. 6 is a diagram illustrating the arrangement relationship between a DC power supply 13 provided outside the substrate 50 and portions of first power supply wiring 14a and second power supply wiring 14b that are wired outside the substrate 50.

FIG. 7 is a cross-sectional view taken along line A₁-A₂ of the laser diode drive circuit 2 illustrated in FIGS. 4 and 5.

FIG. 8 is a configuration diagram illustrating another laser diode drive circuit 2 according to the first embodiment.

FIG. 9 is a configuration diagram illustrating another laser diode drive circuit 2 according to the first embodiment.

FIG. 10 is a configuration diagram illustrating another laser diode drive circuit 2 according to the first embodiment.

FIG. 11 is a diagram illustrating the pattern of a first layer 50a of a substrate 50 on which the laser diode drive circuit 2 illustrated in FIG. 10 is mounted.

FIG. 12 is a configuration diagram illustrating a laser diode drive circuit 2 according to a second embodiment.

FIG. 13 is a configuration diagram illustrating another laser diode drive circuit 2 according to the second embodiment.

FIG. 14 is a configuration diagram illustrating another laser diode drive circuit 2 according to the second embodiment.

FIG. 15 is a configuration diagram illustrating another laser diode drive circuit 2 according to the second embodiment.

### DESCRIPTION OF EMBODIMENTS

In order to describe the present invention further in detail, embodiments for carrying out the invention will be described below by referring to the accompanying drawings.

### First Embodiment

FIG. 1 is a configuration diagram illustrating a communication device including a laser diode drive circuit 2 according to a first embodiment.

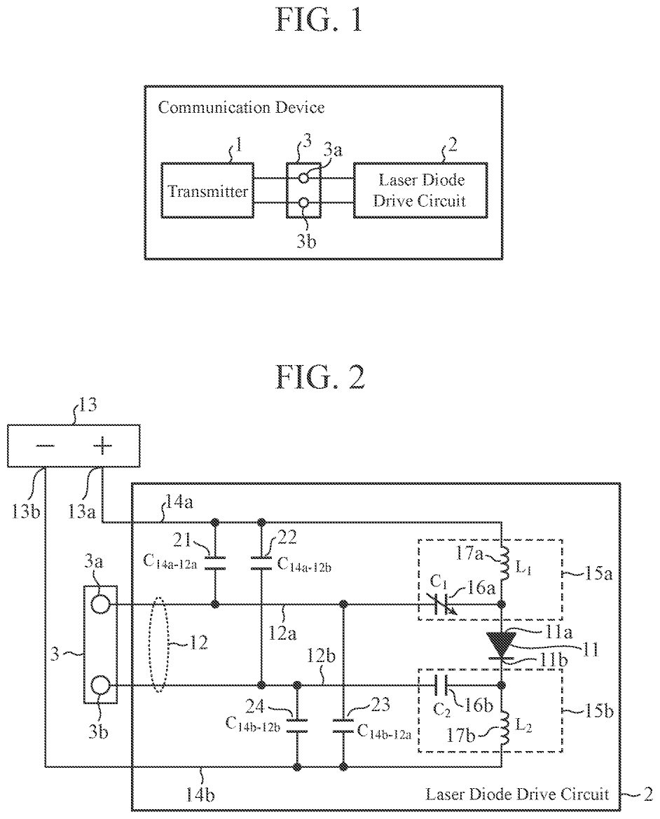

FIG. 2 is a configuration diagram illustrating the laser diode drive circuit 2 according to the first embodiment.

In FIGS. 1 and 2, the communication device includes a transmitter 1 and the laser diode drive circuit 2.

The transmitter 1 outputs a differential high-frequency signal based on a data signal to the laser diode drive circuit 2 via a differential input and output terminal 3.

The communication device illustrated in FIG. 1 includes the transmitter 1. However, this is merely an example, and the communication device illustrated in FIG. 1 may include a receiver instead of the transmitter 1. However, in a case where the communication device illustrated in FIG. 1 includes a receiver instead of the transmitter 1, the laser diode drive circuit 2 includes a light-receiving element for converting light into an electric signal, in place of a laser diode 11 (see FIG. 2) described later.

The laser diode drive circuit 2 connected with the transmitter 1 via the differential input and output terminal 3.

The laser diode drive circuit 2 includes the laser diode 11 that emits light on the basis of a differential high-frequency signal output from the transmitter 1.

The differential input and output terminal 3 includes a first input and output terminal 3a and a second input and output terminal 3b.

In the communication device illustrated in FIG. 1, the differential input and output terminal 3 is provided outside the laser diode drive circuit 2. However, this is merely an example, and the differential input and output terminal 3 may be included inside the laser diode drive circuit 2.

The laser diode 11 includes an anode terminal 11a and a cathode terminal 11b.

The anode terminal 11a is connected with the first input and output terminal 3a via a first signal line 12a. The cathode terminal 11b is connected with the second input and output terminal 3b via a second signal line 12b.

The laser diode 11 emits light on the basis of a differential high-frequency signal output from the transmitter 1.

A differential line 12 includes the first signal line 12a and the second signal line 12b.

The first signal line 12a has one end connected with the anode terminal 11a of the laser diode 11 and the other end connected with the first input and output terminal 3a.

The first signal line 12a transmits the high-frequency signal of the positive electrode side of the differential high-frequency signal output from the transmitter 1 to the anode terminal 11a of the laser diode 11.

The second signal line 12b has one end connected with the cathode terminal 11b of the laser diode 11 and the other end connected with the second input and output terminal 3b.

The second signal line 12b transmits the high-frequency signal of the negative electrode side of the differential high-frequency signal output from the transmitter 1 to the cathode terminal 11b of the laser diode 11.

ADC power supply 13 supplies DC power to the laser diode 11. The DC power supply 13 has a positive side terminal 13a and a negative side terminal 13b.

First power supply wiring 14a has one end connected with the positive side terminal 13a of the DC power supply 13 and the other end connected with the anode terminal 11a of the laser diode 11.

Second power supply wiring 14b has one end connected with the negative side terminal 13b of the DC power supply 13 and the other end connected with the cathode terminal 11b of the laser diode 11.

In the laser diode drive circuit 2 illustrated in FIG. 2, the DC power supply 13 is provided outside the laser diode drive circuit 2. However, this is merely an example, and the DC power supply 13 may be included inside the laser diode drive circuit 2.

A bias tee 15a includes a first capacitor 16a and a first inductor 17a and is connected with the anode terminal 11a of the laser diode 11.

The bias tee 15a combines the high-frequency signal of the positive electrode side transmitted by the first signal line 12a with the positive-side DC power supply current output from the positive side terminal 13a of the DC power supply 13 and outputs the high-frequency signal after the combination with the power supply current to the anode terminal 11a of the laser diode 11.

The first capacitor 16a is inserted in the first signal line 12a and has static capacitance C₁.

The first capacitor 16a is a variable capacitor capable of varying static capacitance C₁.

The first inductor 17a is inserted in the first power supply wiring 14a and has inductance L₁.

The first inductor 17a is inserted in the first power supply wiring 14a so that the high-frequency signal of the positive electrode side transmitted by the first signal line 12a does not flow toward the positive side terminal 13a of the DC power supply 13. For example, in a case where a signal transmitted by the first signal line 12a is a low-frequency signal, for example, a resistor may be inserted in the first power supply wiring 14a instead of the first inductor 17a.

A bias tee 15b includes a second capacitor 16b and a second inductor 17b and is connected with the cathode terminal 11b of the laser diode 11.

The bias tee 15b combines the high-frequency signal of the negative electrode side transmitted by the second signal line 12b with the negative-side DC power supply current flowing toward the negative side terminal 13b of the DC power supply 13 and outputs the high-frequency signal after the combination with the power supply current to the cathode terminal 11b of the laser diode 11.

The second capacitor 16b is inserted in the second signal line 12b and has static capacitance C₂.

The second capacitor 16b is a fixed capacitor of which static capacitance C₂ cannot be changed.

The second inductor 17b is inserted in the second power supply wiring 14b and has inductance L₂.

The second inductor 17b is inserted in the second power supply wiring 14b so that the high-frequency signal of the negative electrode side transmitted by the second signal line 12b does not flow toward the negative side terminal 13b of the DC power supply 13. In a case where a signal transmitted by the second signal line 12b is a low-frequency signal, for example, a resistor may be inserted in the second power supply wiring 14b instead of the second inductor 17b.

First parasitic capacitance 21 is parasitic capacitance C₁₄ₐ₋₁₂ₐ formed between the first power supply wiring 14a and the first signal line 12a. Hereinafter, an area where the first parasitic capacitance 21 is formed between the first power supply wiring 14a and the first signal line 12a is referred to as the “portion forming the first parasitic capacitance 21”.

Second parasitic capacitance 22 is parasitic capacitance C_{14a-12b} formed between the first power supply wiring 14a and the second signal line 12b. Hereinafter, an area where the second parasitic capacitance 22 is formed between the first power supply wiring 14a and the second signal line 12b is referred to as the “portion forming the second parasitic capacitance 22”.

Third parasitic capacitance 23 is parasitic capacitance C₁₄ₐ₋₁₂ₐ formed between the second power supply wiring 14b and the first signal line 12a. Hereinafter, an area where the third parasitic capacitance 23 is formed between the second power supply wiring 14b and the first signal line 12a is referred to as the “portion forming the third parasitic capacitance 23”.

Fourth parasitic capacitance 24 is parasitic capacitance C_{14b-12b} formed between the second power supply wiring 14b and the second signal line 12b. Hereinafter, an area where the fourth parasitic capacitance 24 is formed between the second power supply wiring 14b and the second signal line 12b is referred to as the “portion forming the fourth parasitic capacitance 24”.

Note that separation is made by insulators between the first power supply wiring 14a and the first signal line 12a, between the first power supply wiring 14a and the second signal line 12b, between the second power supply wiring 14b and the first signal line 12a, and between the second power supply wiring 14b and the second signal line 12b, respectively. Parasitic capacitance is generated between a signal line and a power supply wiring separated by an insulator.

In the laser diode drive circuit 2 illustrated in FIG. 2, it is not that a capacitor as the first parasitic capacitance 21, a capacitor as the second parasitic capacitance 22, a capacitor as the third parasitic capacitance 23, or a capacitor as the fourth parasitic capacitance 24 is actually disposed, but the capacitors are illustrated for the purpose of explaining the parasitic capacitance.

Next, the operation of the laser diode drive circuit 2 illustrated in FIG. 2 will be described.

Of a differential high-frequency signal based on a data signal, the transmitter 1 outputs a high-frequency signal of the positive electrode side to the first input and output terminal 3a and outputs the high-frequency signal of the negative electrode side to the second input and output terminal 3b.

The high-frequency signal of the positive electrode side output from the transmitter 1 to the first input and output terminal 3a is transmitted by the first signal line 12a and reaches the bias tee 15a.

Likewise, the high-frequency signal of the negative electrode side output from the transmitter 1 to the second input and output terminal 3b is transmitted by the second signal line 12b and reaches the bias tee 15b.

The bias tee 15a combines the positive-side DC power supply current output from the positive side terminal 13a of the DC power supply 13 with the high-frequency signal of the positive electrode side transmitted by the first signal line 12a.

The bias tee 15a outputs the high-frequency signal of the positive electrode side after the combination with the power supply current to the anode terminal 11a of the laser diode 11.

The bias tee 15b combines the negative-side DC power supply current flowing toward the negative side terminal 13b of the DC power supply 13 with the high-frequency signal of the negative electrode side transmitted by the second signal line 12b.

The bias tee 15b outputs the high-frequency signal of the negative electrode side after the combination with the power supply current to the cathode terminal 11b of the laser diode 11.

Since the high-frequency signal of the positive electrode side after the combination with the power supply current is output from the bias tee 15a to the anode terminal 11a and the high-frequency signal of the negative electrode side after the combination with the power supply current is output from the bias tee 15b to the cathode terminal 11b, the potential of the anode terminal 11a is higher than the potential of the cathode terminal 11b.

The laser diode 11 emits light when the potential difference between the anode terminal 11a and the cathode terminal 11b is higher than the barrier voltage of the laser diode 11.

The laser diode 11 does not emit light when the potential difference between the anode terminal 11a and the cathode terminal 11b is less than or equal to the barrier voltage of the laser diode 11.

In the laser diode drive circuit 2 illustrated in FIG. 2, the first signal line 12a, the second signal line 12b, the first power supply wiring 14a, and the second power supply wiring 14b are each wired.

Therefore, the first parasitic capacitance 21 is formed between the first power supply wiring 14a and the first signal line 12a, and the second parasitic capacitance 22 is formed between the first power supply wiring 14a and the second signal line 12b.

Likewise, the third parasitic capacitance 23 is formed between the second power supply wiring 14b and the first signal line 12a, and the fourth parasitic capacitance 24 is formed between the second power supply wiring 14b and the second signal line 12b.

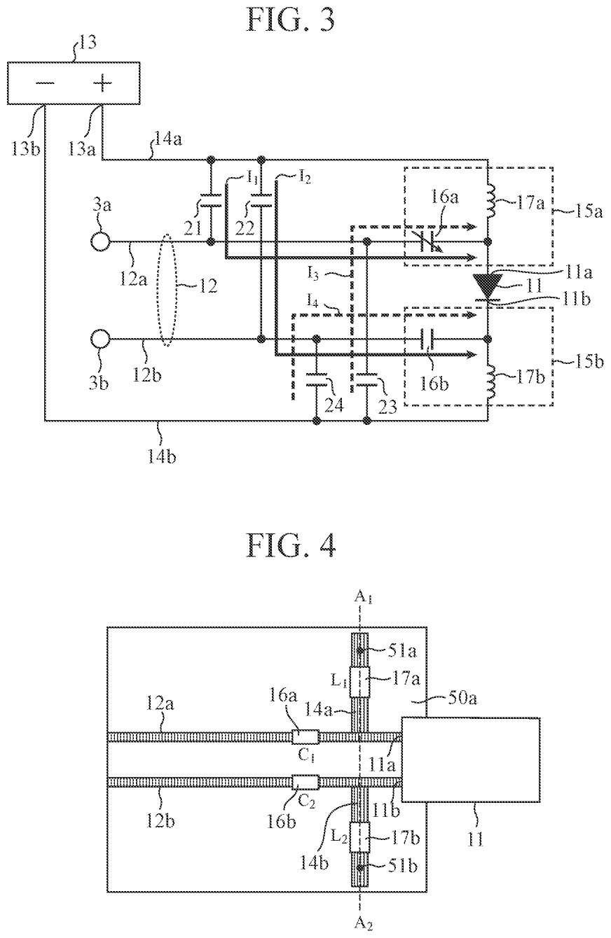

Since the first parasitic capacitance 21, the second parasitic capacitance 22, the third parasitic capacitance 23, and the fourth parasitic capacitance 24 are each formed, noise currents I₁ to I₄ flow in the differential line 12 as illustrated in FIG. 3.

FIG. 3 is an explanatory diagram illustrating paths of noise currents I₁ to I₄ flowing in the differential line 12.

Noise current I₁ is generated by being guided from the first power supply wiring 14a to the first signal line 12a via the portion forming the first parasitic capacitance 21. The path of noise current I₁ is as follows.

First power supply wiring 14a-> portion forming first parasitic capacitance 21 -> first signal line 12a-> anode terminal 11a of laser diode 11

Noise current I₂ is generated by being guided from the first power supply wiring 14a to the second signal line 12b via the portion forming the second parasitic capacitance 22. The path of noise current 12 is as follows.

First power supply wiring 14a-> portion forming second parasitic capacitance 22-> second signal line 12b-> cathode terminal 11b of laser diode 11

Noise current I₃ is generated by being guided from the second power supply wiring 14b to the first signal line 12a via the portion forming the third parasitic capacitance 23. The path of noise current 13 is as follows.

Second power supply wiring 14b-> portion forming third parasitic capacitance 23-> first signal line 12a-> anode terminal 11a of laser diode 11

Noise current I₄ is generated by being guided from the second power supply wiring 14b to the second signal line 12b via the portion forming the fourth parasitic capacitance 24. The path of noise current 14 is as follows.

Second power supply wiring 14b-> portion forming fourth parasitic capacitance 24-> second signal line 12b-> cathode terminal 11b of laser diode 11

For example, in a case where static capacitance C₁ of the first capacitor 16a and static capacitance C₂ of the second capacitor 16b are the same, let us assume a case where the first parasitic capacitance 21 and the fourth parasitic capacitance 24 are different or a case where the second parasitic capacitance 22 and the third parasitic capacitance 23 are different.

Alternatively, let us assume a case where the first parasitic capacitance 21 and the fourth parasitic capacitance 24 are different and the second parasitic capacitance 22 and the third parasitic capacitance 23 are different in a case where static capacitance C₁ of the first capacitor 16a and static capacitance C₂ of the second capacitor 16b are the same.

In these assumptions, there are cases where the potential difference between the anode terminal 11a and the cathode terminal 11b fluctuates when noise currents I₁ and I₃ flow through the first signal line 12a and reach the anode terminal 11a and noise currents I₂ and I₄ flow through the second signal line 12b and reach the cathode terminal 11b.

In a case where the potential difference between the anode terminal 11a and the cathode terminal 11b fluctuates associated with the generation of noise currents I₁ to I₄, the laser diode 11 may erroneously emit light or erroneously go off.

Here, let us assume that the combined capacitance of static capacitance C₁ of the first capacitor 16a and the first parasitic capacitance 21 is GC_{1,14a-12a} (see Equation 1 below) and that the combined capacitance of static capacitance C₂ of the second capacitor 16b and the fourth parasitic capacitance 24 is GC_{2,14b-12b} (see Equation 2 below).

Likewise, let us assume that the combined capacitance of static capacitance C₁ of the first capacitor 16a and the third parasitic capacitance 23 is GC_{1,14b-12a} (see Equation 3 below) and that the combined capacitance of static capacitance C₂ of the second capacitor 16b and the second parasitic capacitance 22 is GC_{2,14a-12b} (see Equation 4 below).

$$\begin{matrix}G {C}_{1 , 14 a - 12 a} = \frac{{C}_{1} \times {C}_{14 a - 12 a}}{{C}_{1} + {C}_{14 a - 12 a}} & ( 1 ) \\ G {C}_{2 , 14 b - 12 b} = \frac{{C}_{2} \times {C}_{14 b - 12 b}}{{C}_{2} + {C}_{14 b - 12 b}} & ( 2 ) \\ G {C}_{1 , 14 b - 12 a} = \frac{{C}_{1} \times {C}_{14 b - 12 a}}{{C}_{1} + {C}_{14 b - 12 a}} & ( 3 ) \\ G {C}_{2 , 14 a - 12 b} = \frac{{C}_{2} \times {C}_{14 a - 12 b}}{{C}_{2} + {C}_{14 a - 12 b}} & ( 4 )\end{matrix}$$

In a case where combined capacitance GC_{1,14a-12a} and combined capacitance GC_{2,14b-12b} are different or combined capacitance GC_{1,14b-12a} and combined capacitance GC_{2,14a-12b} are different, there may be a difference between the sum of noise current I₁ and noise current I₃ and the sum of noise current I₂ and noise current I₄.

In addition, in a case where combined capacitance GC_{1,14a-12a} and combined capacitance GC_{2,14b-12b} are different and combined capacitance GC_{1,14b-12a} and combined capacitance GC_{2,14a-12b} are different, there may be a difference between the sum of noise current I₁ and noise current I₃ and the sum of noise current I₂ and noise current I₄.

When there is a difference between the sum of noise current I₁ and noise current I₃ and the sum of noise current I₂ and noise current I₄, the potential difference between the anode terminal 11a and the cathode terminal 11b may fluctuate.

On the other hand, when combined capacitance GC_{1,14a-12a} and combined capacitance GC_{2,14b-12b} are equal and combined capacitance GC_{1,14b-12a} and combined capacitance GC_{2,14a-12b} are equal, the sum of noise current I₁ and noise current I₃ and the sum of noise current I₂ and noise current I₄ are equal. When the sum of noise current I₁ and noise current I₃ and the sum of noise current I₂ and noise current I₄ are equal, the potential difference between the anode terminal 11a and the cathode terminal 11b does not fluctuate even if noise currents I₁ to I₄ are generated. When the potential difference between the anode terminal 11a and the cathode terminal 11b does not fluctuate, the laser diode 11 does not erroneously emit light nor erroneously goes off.

In the laser diode drive circuit 2 illustrated in FIG. 2, static capacitance C₁ of the first capacitor 16a, which is a variable capacitor, is adjusted so that combined capacitance GC_{1,14a-12a} and combined capacitance GC_{2,14b-12b} are equal and that combined capacitance GC_{1,14b-12a} and combined capacitance GC_{2,14a-12b} are equal.

Hereinafter, the configuration of a case where the laser diode drive circuit 2 illustrated in FIG. 2 is mounted on a substrate 50 having a two-layer structure will be described.

FIG. 4 is a diagram illustrating the pattern of a first layer 50a of the substrate 50 on which the laser diode drive circuit 2 illustrated in FIG. 2 is mounted.

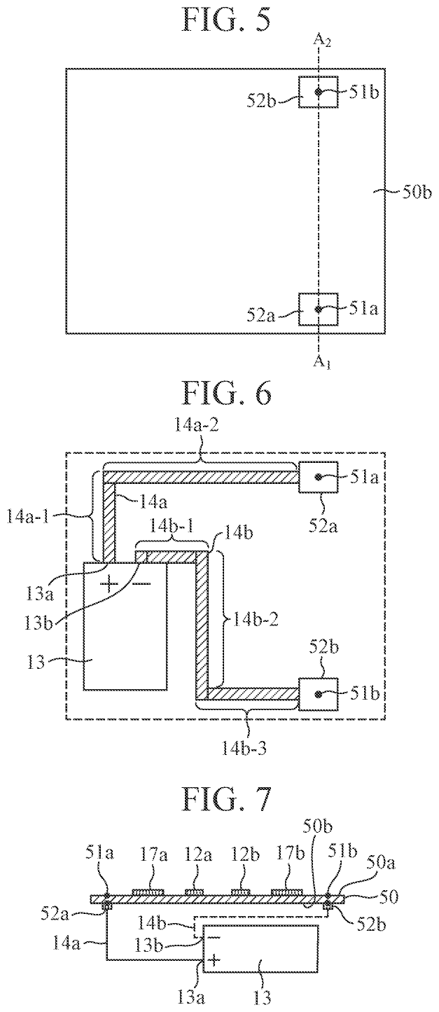

FIG. 5 is a diagram illustrating the pattern of a second layer 50b of the substrate 50 on which the laser diode drive circuit 2 illustrated in FIG. 2 is mounted.

FIG. 6 is a diagram illustrating the arrangement relationship between the DC power supply 13 provided outside the substrate 50 and portions of the first power supply wiring 14a and the second power supply wiring 14b that are wired outside the substrate 50.

FIG. 7 is a cross-sectional view taken along line A₁-A₂ of the laser diode drive circuit 2 illustrated in FIGS. 4 and 5.

In FIGS. 4 to 7, the first capacitor 16a, the second capacitor 16b, the first inductor 17a, and the second inductor 17b are mounted on the first layer 50a of the substrate 50.

The first signal line 12a, the second signal line 12b, a part of the first power supply wiring 14a, and a part of the second power supply wiring 14b are also wired on the first layer 50a of the substrate 50.

In addition, a part of the laser diode 11 is mounted on the first layer 50a of the substrate 50.

The first power supply wiring 14a wired on the first layer 50a of the substrate 50 is connected with one end of a via 51a, and the other end of the via 51a is connected with a conductor 52a wired on the second layer 50b of the substrate 50.

The second power supply wiring 14b wired on the first layer 50a of the substrate 50 is connected with one end of a via 51b, and the other end of the via 51b is connected with a conductor 52b wired on the second layer 50b of the substrate 50.

First power supply wiring 14a-1 and 14a-2 are portions of the first power supply wiring 14a that are wired outside the substrate 50.

The first power supply wiring 14a-1 has one end connected with the positive side terminal 13a of the DC power supply 13 and the other end connected with one end of the first power supply wiring 14a-2.

The first power supply wiring 14a-2 has the one end connected with the other end of the first power supply wiring 14a-1 and the other end connected with the conductor 52a.

The second power supply wiring 14b-1, 14b-2, and 14b-3 are portions of the second power supply wiring 14b that are wired outside the substrate 50.

The second power supply wiring 14b-1 has one end connected with the negative side terminal 13b of the DC power supply 13 and the other end connected with one end of the second power supply wiring 14b-2.

The second power supply wiring 14b-2 has one end connected with the other end of the second power supply wiring 14b-1 and the other end connected with one end of the second power supply wiring 14b-3.

The second power supply wiring 14b-3 has the one end connected with the other end of the second power supply wiring 14b-2 and the other end connected with the conductor 52b.

In the arrangement example of FIG. 6, the first power supply wiring 14a-2 is disposed parallel to each of the first signal line 12a and the second signal line 12b, and the first power supply wiring 14a-2 is electrically coupled with each of the first signal line 12a and the second signal line 12b.

Since the distance between the first power supply wiring 14a-2 and the first signal line 12a is shorter than the distance between the first power supply wiring 14a-2 and the second signal line 12b, the amount of coupling between the first power supply wiring 14a-2 and the first signal line 12a is larger than the amount of coupling between the first power supply wiring 14a-2 and the second signal line 12b.

In the arrangement example of FIG. 6, the second power supply wiring 14b-1 is disposed parallel to each of the first signal line 12a and the second signal line 12b, and the second power supply wiring 14b-1 is electrically coupled with each of the first signal line 12a and the second signal line 12b.

Since the distance between the second power supply wiring 14b-1 and the first signal line 12a is shorter than the distance between the second power supply wiring 14b-1 and the second signal line 12b, the amount of coupling between the second power supply wiring 14b-1 and the first signal line 12a is larger than the amount of coupling between the second power supply wiring 14b-1 and the second signal line 12b.

In the arrangement example of FIG. 6, the second power supply wiring 14b-3 is disposed parallel to each of the first signal line 12a and the second signal line 12b, and the second power supply wiring 14b-3 is electrically coupled with each of the first signal line 12a and the second signal line 12b.

Since the distance between the second power supply wiring 14b-3 and the first signal line 12a is longer than the distance between the second power supply wiring 14b-3 and the second signal line 12b, the amount of coupling between the second power supply wiring 14b-3 and the first signal line 12a is smaller than the amount of coupling between the second power supply wiring 14b-3 and the second signal line 12b.

Note that, since the second power supply wiring 14b-3 has a longer distance from each of the first signal line 12a and the second signal line 12b than the second power supply wiring 14b-1 has, the amount of coupling between the second power supply wiring 14b-3 and the first signal line 12a is smaller than the amount of coupling between the second power supply wiring 14b-1 and the first signal line 12a. Likewise, the amount of coupling between the second power supply wiring 14b-3 and the second signal line 12b is smaller than the amount of coupling between the second power supply wiring 14b-1 and the second signal line 12b. Here, for the sake of simplicity of the explanation, the line length of the second power supply wiring 14b-1 and the line length of the second power supply wiring 14b-3 are neglected.

Therefore, the amount of coupling between power supply wiring obtained by adding the second power supply wiring 14b-1 and the second power supply wiring 14b-3 and the first signal line 12a is larger than the amount of coupling between the power supply wiring obtained by adding the second power supply wiring 14b-1 and the second power supply wiring 14b-3 and the second signal line 12b.

In FIG. 6, the arrangement example is illustrated in which the average distance between the power supply wiring obtained by adding the second power supply wiring 14b-1 and the second power supply wiring 14b-3 and the second signal line 12b is shorter than the distance between the first power supply wiring 14a-2 and the first signal line 12a.

In the arrangement example of FIG. 6, the amount of coupling between the power supply wiring obtained by adding the second power supply wiring 14b-1 and the second power supply wiring 14b-3 and the second signal line 12b is larger than the amount of coupling between the first power supply wiring 14a-2 and the first signal line 12a.

From the above, in the arrangement example of FIG. 6, the first parasitic capacitance 21 formed between the first power supply wiring 14a and the first signal line 12a is different from the fourth parasitic capacitance 24 formed between the second power supply wiring 14b and the second signal line 12b.

Likewise, the third parasitic capacitance 23 formed between the second power supply wiring 14b and the first signal line 12a is different from the second parasitic capacitance 22 formed between the first power supply wiring 14a and the second signal line 12b.

Therefore, when static capacitance C₁ of the first capacitor 16a and static capacitance C₂ of the second capacitor 16b are the same, combined capacitance GC_{1,14a-12}a and combined capacitance GC_{2,14b-12b} are different and combined capacitance GC_{1,14b-12a} and combined capacitance GC_{2,14a-12b} are different.

In the laser diode drive circuit 2 illustrated in FIG. 2, static capacitance C₁ of the first capacitor 16a, which is a variable capacitor, is adjusted so that combined capacitance GC_{1,14a-12a} and combined capacitance GC_{2,14b-12b} are equal and that combined capacitance GC_{1,14b-12a} and combined capacitance GC_{2,14a-12b}are equal.

In the laser diode drive circuit 2 illustrated in FIG. 2, since static capacitance C₁ of the first capacitor 16a is adjusted, the potential difference between the anode terminal 11a and the cathode terminal 11b does not fluctuate even when noise currents I₁ to I₄ are generated.

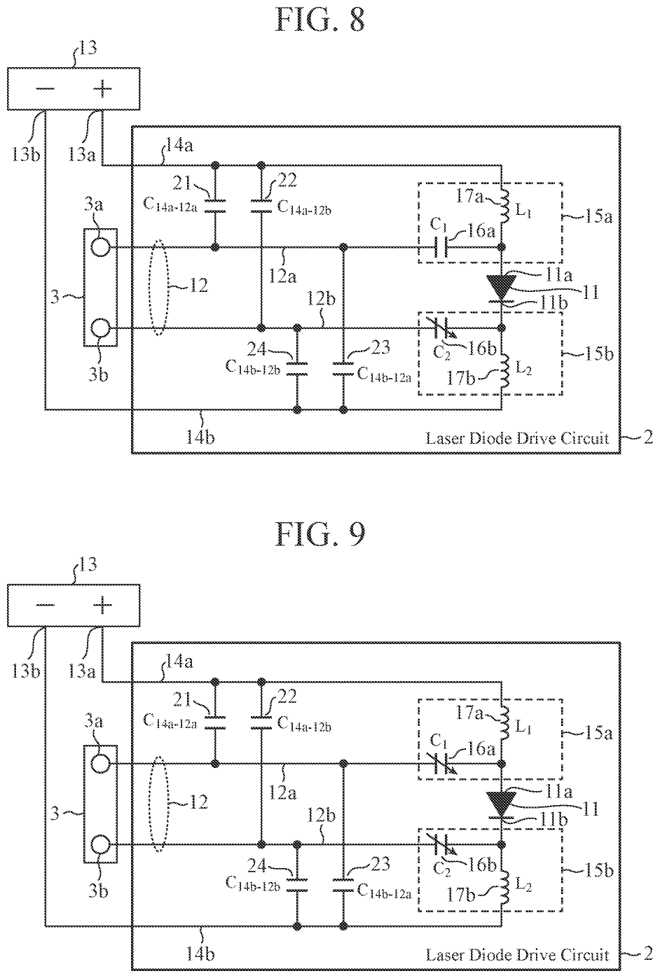

In the laser diode drive circuit 2 illustrated in FIG. 2, the first capacitor 16a is a variable capacitor, and the second capacitor 16b is a fixed capacitor. However, this is merely an example, and, for example, as illustrated in FIG. 8, the first capacitor 16a may be a fixed capacitor, and the second capacitor 16b may be a variable capacitor.

FIG. 8 is a configuration diagram illustrating another laser diode drive circuit 2 according to the first embodiment.

It is also possible to make combined capacitance GC_{1,14a-12a} and combined capacitance GC_{2,14b-12b} equal to each other and combined capacitance GC_{1,14b-12a} and combined capacitance GC_{2,14a-12b} equal to each other by adjusting static capacitance C₂ of the second capacitor 16b which is a variable capacitor.

Therefore, also by adjusting static capacitance C₂ of the second capacitor 16b, it is possible to prevent both of erroneous emission of light and erroneous extinction of light of the laser diode 11 as in the laser diode drive circuit 2 illustrated in FIG. 2.

Alternatively, as illustrated in FIG. 9, the first capacitor 16a and the second capacitor 16b may be both variable capacitors.

FIG. 9 is a configuration diagram illustrating another laser diode drive circuit 2 according to the first embodiment.

Also by adjusting each of static capacitance C₁ of the first capacitor 16a and static capacitance C₂ of the second capacitor 16b, it is possible to make combined capacitance GC_{1,14a-12a} and combined capacitance GC_{2,14b-12b} equal to each other and combined capacitance GC_{1,14b-12a} and combined capacitance GC_{2,14a-12b} equal to each other.

Therefore, also by adjusting each of static capacitance C₁ of the first capacitor 16a and static capacitance C₂ of the second capacitor 16b, it is possible to prevent both of erroneous emission of light and erroneous extinction of light of the laser diode 11 as in the laser diode drive circuit 2 illustrated in FIG. 2.

In a case where static capacitance C₁ of the first capacitor 16a and static capacitance C₂ of the second capacitor 16b are each adjusted, the adjustment range of the combined capacitance is wider than that in the case where only static capacitance C₁ of the first capacitor 16a is adjusted.

Specifically, in a case where the difference between combined capacitance GC_{1,14a-12a} and combined capacitance GC_{2,14b-12b} or the difference between combined capacitance GC_{1,14b-12a} and combined capacitance GC_{2,14a-12b} is large, there are cases where it is not possible to make combined capacitance GC_{1,14a-12a} and combined capacitance GC_{2,14b-12b} equal to each other and also to make combined capacitance GC_{1,14b-12a} and combined capacitance GC_{2,14a-12b} equal to each other if only static capacitance C₁ of the first capacitor 16a is adjusted.

However, even in a case where the difference is large, by adjusting each of static capacitance C₁ of the first capacitor 16a and static capacitance C₂ of the second capacitor 16b, it is possible to make combined capacitance GC_{1,14a-12a} and combined capacitance GC_{2,14b-12b} equal to each other and also to make combined capacitance GC_{1,14b-12a} and combined capacitance GC_{2,14a-12b} equal to each other.

In the above-described first embodiment, the laser diode drive circuit 2 is configured so that at least one of the first capacitor 16a and the second capacitor 16b is a variable capacitor. Therefore, the laser diode drive circuit 2 is capable of preventing both of erroneous emission of light and erroneous extinction of light of the laser diode 11 even when noise is induced to the differential line 12 from the first power supply wiring 14a and the second power supply wiring 14b via the portions forming parasitic capacitance.

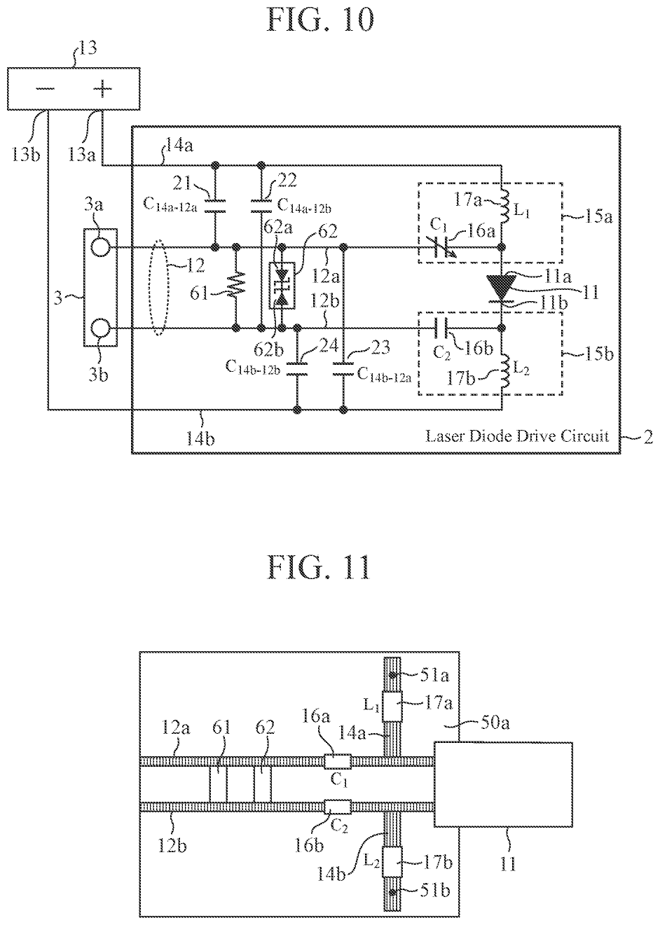

FIG. 10 is a configuration diagram illustrating another laser diode drive circuit 2 according to the first embodiment.

FIG. 11 is a diagram illustrating the pattern of a first layer 50a of a substrate 50 on which the laser diode drive circuit 2 illustrated in FIG. 10 is mounted.

In FIGS. 10 and 11, the same symbols as those in FIGS. 2 and 4 represent the same or corresponding parts.

A resistor 61 has one end connected with the first signal line 12a and the other end connected with the second signal line 12b.

A protection circuit 62 has one end connected with the first signal line 12a and the other end connected with the second signal line 12b.

The protection circuit 62 is implemented by, for example, a Zener diode 62a and a Zener diode 62b.

In the Zener diode 62a, its anode terminal is connected with the first signal line 12a, and its cathode terminal is connected with a cathode terminal of the Zener diode 62b.

In the Zener diode 62b, its anode terminal is connected with the second signal line 12b, and its cathode terminal is connected with the cathode terminal of the Zener diode 62a.

The resistor 61 is used for matching of the impedance of the first signal line 12a with the impedance of the second signal line 12b.

The protection circuit 62 is used to prevent an excessive noise current I₁ flowing through the first signal line 12a from entering the second signal line 12b, and the protection circuit 62 is used to prevent an excessive noise current 13 flowing through the first signal line 12a from entering the second signal line 12b.

The protection circuit 62 is also used to prevent an excessive noise current I₂ flowing through the second signal line 12b from entering the first signal line 12a, and the protection circuit 62 is used to prevent an excessive noise current I₄ flowing through the second signal line 12b from entering the first signal line 12a.

Like the laser diode drive circuit 2 illustrated in FIG. 2, the laser diode drive circuit 2 illustrated in FIG. 10 is capable of preventing both erroneous emission of light and erroneous extinction of light of the laser diode. Furthermore, since the laser diode drive circuit 2 illustrated in FIG. 10 includes the resistor 61, the impedance of the first signal line 12a can be matched with the impedance of the second signal line 12b.

Since the laser diode drive circuit 2 illustrated in FIG. 10 includes the protection circuit 62, it is possible to prevent the excessive noise currents I₁ and I₃ flowing through the first signal line 12a from entering the second signal line 12b and to prevent the excessive noise currents I₂ and I₄ flowing through the second signal line 12b from entering the first signal line 12a.

### Second Embodiment

In the laser diode drive circuit 2 of the first embodiment, the first inductor 17a is inserted in the first power supply wiring 14a.

In a second embodiment, a laser diode drive circuit 2 in which a first inductor 17a and a first variable inductor 71a are inserted in first power supply wiring 14a will be described.

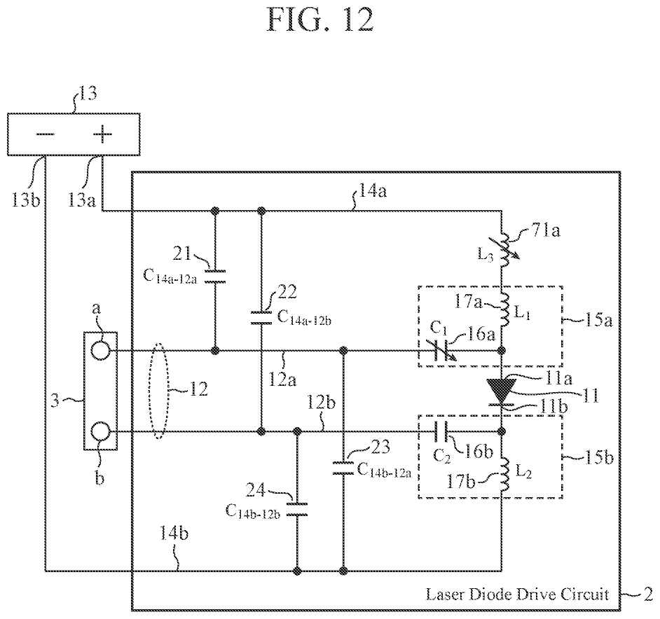

FIG. 12 is a configuration diagram illustrating the laser diode drive circuit 2 according to the second embodiment. In FIG. 12, the same symbols as those in FIG. 2 represent the same or corresponding parts, and thus description thereof is omitted.

The first variable inductor 71a is inserted in the first power supply wiring 14a.

The first variable inductor 71a has inductance L₃, and inductance L₃ can be adjusted so that a winding error of each coil in the first inductor 17a and the second inductor 17b is compensated.

In the first variable inductor 71a, inductance L₃ changes, for example, by adjusting a relative position between the core and the winding and thereby adjusting magnetic permeability.

In the laser diode drive circuit 2 illustrated in FIG. 12, the first variable inductor 71a has one end connected with the positive side terminal 13a of the DC power supply 13 and the other end connected with one end of the first inductor 17a. However, this is merely an example, and the one end of the first variable inductor 71a may be connected with the other end of the first inductor 17a, and the other end of the first variable inductor 71a may be connected with the anode terminal 11a of the laser diode 11.

Next, the operation of the laser diode drive circuit 2 illustrated in FIG. 12 will be described.

There are cases where the coil included the first inductor 17a has a winding error as a manufacturing error.

The coil included the second inductor 17b may also have a winding error as a manufacturing error in some cases.

Therefore, there are cases where inductance L₁ of the first inductor 17a is different from the design inductance and inductance L₂ of the second inductor 17b is different from the design inductance.

When inductances L₁ and L₂ are different from the design inductance, the laser diode 11 may not emit light in accordance with a differential high-frequency signal based on a data signal output from a transmitter 1.

For example, let us assume that, in a case where the design inductance of the first inductor 17a and the design inductance of the second inductor 17b are the same, each coil in the first inductor 17a and the second inductor 17b has a winding error.

Let us further assume that inductance L₁ of the first inductor 17a is smaller than inductance L₂ of the second inductor 17b (L₁<L₂) since each of the coils has a winding error.

In the laser diode drive circuit 2 illustrated in FIG. 12, inductance L₃ of the first variable inductor 71a is adjusted so that the sum of inductance L₁ and inductance L₃ of the first variable inductor 71a (L₁+L₃) is equal to inductance L₂.

By adjusting inductance L₃ of the first variable inductor 71a, a winding error of each of the coils in the first inductor 17a and the second inductor 17b is compensated.

For example, let us assume that, in a case where the design inductance of the first inductor 17a is smaller than the design inductance of the second inductor 17b by ΔL_{1, 2,} each of the coils in the first inductor 17a and the second inductor 17b has a winding error.

Let us further assume that inductance L₁ is smaller than inductance L₂ and that the difference between inductance L₁ and inductance L₂ (L₂-L₁) is larger than ΔL_{1, 2} (L₂-L₁>ΔL_{1, 2}) since each of the coils has a winding error.

In the laser diode drive circuit 2 illustrated in FIG. 12, inductance L₃ of the first variable inductor 71a is adjusted so that the difference between the sum (L₁+L₃) of inductance L₁ and inductance L₃ and inductance L₂ (L₂-(L₁+L₃)) is equal to ΔL_{1, 2}.

By adjusting inductance L₃ of the first variable inductor 71a, a winding error of each of the coils in the first inductor 17a and the second inductor 17b is compensated.

In the second embodiment described above, the laser diode drive circuit 2 includes the first variable inductor 71a inserted in the first power supply wiring 14a, and the first variable inductor 71a can be adjusted so that a winding error of each of the coils in the first inductor 17a and the second inductor 17b is compensated. Therefore, the laser diode drive circuit 2 is capable of preventing both erroneous emission of light and erroneous extinction of light of the laser diode even if each of the coils in the first inductor 17a and the second inductor 17b has a winding error.

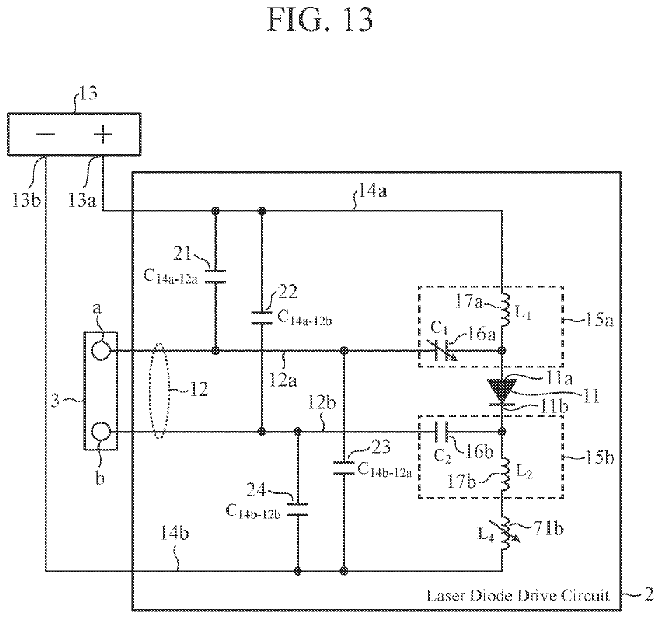

In the laser diode drive circuit 2 illustrated in FIG. 12, the first variable inductor 71a is inserted in the first power supply wiring 14a. However, this is merely an example, and, for example, a second variable inductor 71b may be inserted in the second power supply wiring 14b in the laser diode drive circuit 2 as illustrated in FIG. 13.

FIG. 13 is a configuration diagram illustrating another laser diode drive circuit 2 according to the second embodiment.

A second variable inductor 71b is inserted in the second power supply wiring 14b.

The second variable inductor 71b has inductance L₄, and inductance L₄ can be adjusted so that a winding error of each of the coils in the first inductor 17a and the second inductor 17b is compensated.

In the second variable inductor 71b, inductance L₄ changes, for example, by adjusting a relative position between the core and the winding and thereby adjusting magnetic permeability.

In the laser diode drive circuit 2 illustrated in FIG. 13, the second variable inductor 71b has one end connected with the negative side terminal 13b of the DC power supply 13 and the other end connected with one end of the second inductor 17b. However, this is merely an example, and the one end of the second variable inductor 71b may be connected with the other end of the second inductor 17b, and the other end of the second variable inductor 71b may be connected with the cathode terminal 11b of the laser diode 11.

For example, let us assume that, in a case where the design inductance of the first inductor 17a and the design inductance of the second inductor 17b are the same, each coil in the first inductor 17a and the second inductor 17b has a winding error.

Let us further assume that inductance L₁ of the first inductor 17a is larger than inductance L₂ of the second inductor 17b (L₁>L₂) since each of the coils has a winding error.

In the laser diode drive circuit 2 illustrated in FIG. 13, inductance L₄ of the second variable inductor 71b is adjusted so that the sum of inductance L2 and inductance L₄ of the second variable inductor 71b (L₂+L₄) is equal to inductance L₁.

By adjusting inductance L₄ of the second variable inductor 71b, a winding error of each of the coils in the first inductor 17a and the second inductor 17b is compensated.

For example, let us assume that, in a case where the design inductance of the first inductor 17a is larger than the design inductance of the second inductor 17b by ΔL_{1, 2,} each of the coils in the first inductor 17a and the second inductor 17b has a winding error.

Let us further assume that inductance L₁ is larger than inductance L₂ and that the difference between inductance L₁ and inductance L₂ (L₁-L₂) is larger than ΔL_{1, 2} (L₁-L₂>ΔL_{1, 2}) since each of the coils has a winding error.

In the laser diode drive circuit 2 illustrated in FIG. 13, inductance L₄ of the second variable inductor 71b is adjusted so that the difference between the sum (L₂30 L₄) of inductance L₂ and inductance L₄ and inductance L₁ (L₁−(L₂+L₄)) is equal to ΔL_{1, 2.}

By adjusting inductance L₄ of the second variable inductor 71b, a winding error of each of the coils in the first inductor 17a and the second inductor 17b is compensated.

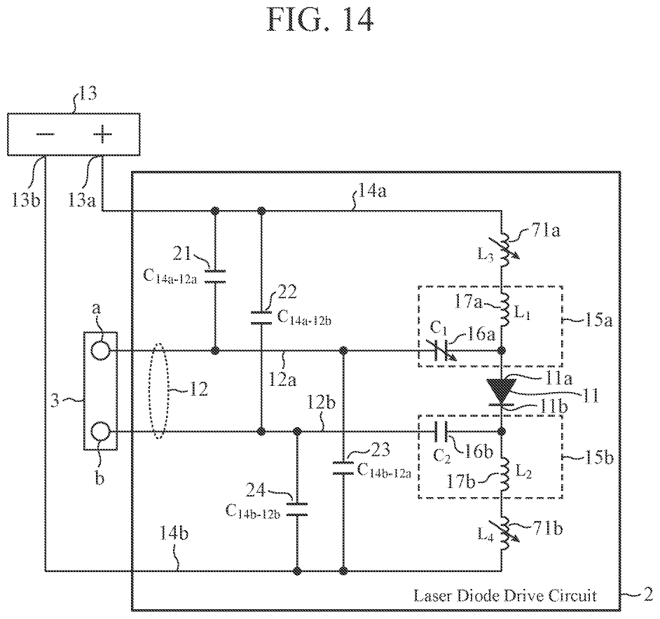

In the laser diode drive circuit 2 illustrated in FIG. 12, the first variable inductor 71a is inserted in the first power supply wiring 14a. However, this is merely an example, and, for example, as illustrated in FIG. 14, the first variable inductor 71a may be inserted in the first power supply wiring 14a, and the second variable inductor 71b may be inserted in the second power supply wiring 14b in the laser diode drive circuit 2.

FIG. 14 is a configuration diagram illustrating another laser diode drive circuit 2 according to the second embodiment.

Since the laser diode drive circuit 2 includes the first variable inductor 71a and the second variable inductor 71b, it is possible to compensate for a larger winding error than in the laser diode drive circuit 2 illustrated in FIG. 12.

In the laser diode drive circuit 2 illustrated in FIG. 12, the first variable inductor 71a is inserted in the first power supply wiring 14a.

Instead of inserting the first variable inductor 71a in the first power supply wiring 14a, a variable inductor may be used as the first inductor 17a in the laser diode drive circuit 2.

In a case where the laser diode drive circuit 2 uses a variable inductor as the first inductor 17a, inductance L₁ of the first inductor 17a is adjusted so that a winding error of each of the coils in the first inductor 17a and the second inductor 17b is compensated. Therefore, the winding error of each of the coils can be compensated as in the case where the first variable inductor 71a is inserted in the first power supply wiring 14a.

Alternatively, instead of the first variable inductor 71a inserted in the first power supply wiring 14a, a variable inductor may be used as the second inductor 17b in the laser diode drive circuit 2. Further alternatively, instead of the first variable inductor 71a inserted in the first power supply wiring 14a, a variable inductor may be used as the first inductor 17a, and a variable inductor may be used as the second inductor 17b in the laser diode drive circuit 2.

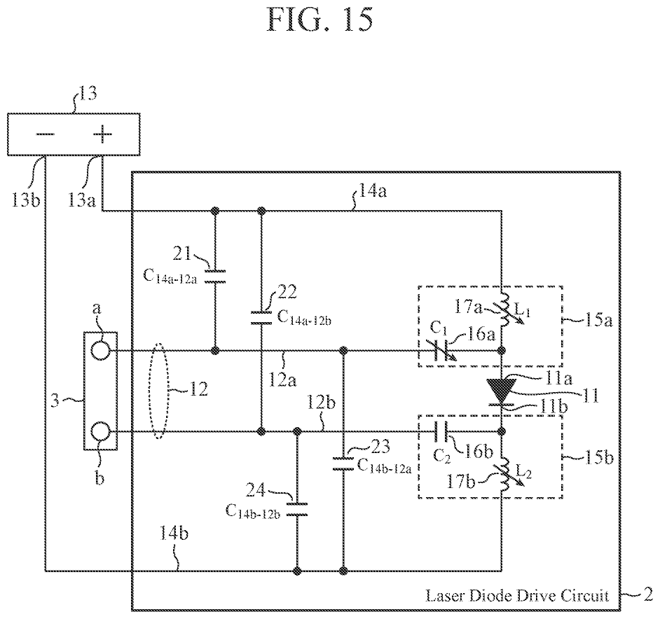

FIG. 15 is a configuration diagram illustrating another laser diode drive circuit 2 according to the second embodiment.

In the laser diode drive circuit 2 illustrated in FIG. 15, a first inductor 17a and a second inductor 17b are both variable inductors.

In the laser diode drive circuit 2 illustrated in FIGS. 12 to 15, the first capacitor 16a is a variable capacitor, and the second capacitor 16b is a fixed capacitor. However, this is merely an example, and the first capacitor 16a may be a fixed capacitor, and the second capacitor 16b may be a variable capacitor.

Alternatively, both the first capacitor 16a and the second capacitor 16b may be variable capacitors.

Note that the present invention may include a flexible combination of the embodiments, a modification of any component of the embodiments, or an omission of any component in the embodiments within the scope of the present invention.

### INDUSTRIAL APPLICABILITY

The present invention is suitable for a laser diode drive circuit including a laser diode and a communication device.

### REFERENCE SIGNS LIST

1: transmitter, 2: laser diode drive circuit, 3: differential input and output terminal, 3a: first input and output terminal, 3b: second input and output terminal, 11: laser diode, 11a: anode terminal, 11b: cathode terminal, 12: differential line, 12a: first signal line, 12b: second signal line, 13: DC power supply, 13a: positive side terminal, 13b: negative side terminal, 14a, 14a-1, 14a-2: first power supply wiring, 14b, 14b-1, 14b-2, 14b-3: second power supply wiring, 15a, 15b: bias tee, 16a: first capacitor, 16b: second capacitor, 17a: first inductor, 17b: second inductor, 21: first parasitic capacitance, 22: second parasitic capacitance, 23: third parasitic capacitance, 24: fourth parasitic capacitance, 50: substrate, 50a: first layer, 50b: second layer, 51a: via, 51b: via, 52a: conductor, 52b: conductor, 61: resistor, 62: protection circuit, 62a, 62b: Zener diode, 71a: first variable inductor, 71b: second variable inductor

1. A laser diode drive circuit comprising:
a laser diode;
a differential line including a first signal line having a first end connected with an anode terminal of the laser diode and a second signal line having a first end connected with a cathode terminal of the laser diode;
first power supply wiring having a first end connected with a positive side terminal of a direct current power supply and a second end connected with the anode terminal;
second power supply wiring having a first end connected with a negative side terminal of the direct current power supply and a second end connected with the cathode terminal;
a first capacitor inserted in the first signal line; and
a second capacitor inserted in the second signal line,
wherein at least one of the first capacitor and the second capacitor is a variable capacitor.

2. The laser diode drive circuit according to claim 1,
wherein parasitic capacitance formed between the first power supply wiring and the first signal line is first parasitic capacitance,
parasitic capacitance formed between the first power supply wiring and the second signal line is second parasitic capacitance,
parasitic capacitance formed between the second power supply wiring and the first signal line is third parasitic capacitance,
parasitic capacitance formed between the second power supply wiring and the second signal line is fourth parasitic capacitance, and
the variable capacitor is adjustable so that combined capacitance of static capacitance of the first capacitor and the first parasitic capacitance is equal to combined capacitance of static capacitance of the second capacitor and the fourth parasitic capacitance and that combined capacitance of static capacitance of the first capacitor and the third parasitic capacitance is equal to combined capacitance of static capacitance of the second capacitor and the second parasitic capacitance.

3. The laser diode drive circuit according to claim 1, further comprising:
a first inductor inserted in the first power supply wiring; and
a second inductor inserted in the second power supply wiring.

4. The laser diode drive circuit according to claim 3, further comprising:
a first variable inductor inserted in the first power supply wiring,
wherein the first variable inductor is adjustable so that a winding error of each of coils in the first inductor and the second inductor is compensated.

5. The laser diode drive circuit according to claim 3, further comprising:
a second variable inductor inserted in the second power supply wiring,
wherein the second variable inductor is adjustable so that a winding error of each of coils in the first inductor and the second inductor is compensated.

6. The laser diode drive circuit according to claim 3, further comprising:
a first variable inductor inserted in the first power supply wiring; and
a second variable inductor inserted in the second power supply wiring,
wherein inductance of the first variable inductor and inductance of the second variable inductor are each adjustable so that a winding error of each of coils in the first inductor and the second inductor is compensated.

7. The laser diode drive circuit according to claim 3,
wherein at least one of the first inductor and the second inductor is a variable inductor, and
the variable inductor is adjustable so that a winding error of each of coils in the first inductor and the second inductor is compensated.

8. A communication device comprising a laser diode drive circuit,
wherein the laser diode drive circuit includes:
a laser diode;
a differential line including a first signal line having a first end connected with an anode terminal of the laser diode and a second signal line having a first end connected with a cathode terminal of the laser diode;
first power supply wiring having a first end connected with a positive side terminal of a direct current power supply and a second end connected with the anode terminal;
second power supply wiring having a first end connected with a negative side terminal of the direct current power supply and a second end connected with the cathode terminal;
a first capacitor inserted in the first signal line; and
a second capacitor inserted in the second signal line, and at least one of the first capacitor and the second capacitor is a variable capacitor.
